(19) United States
(12) Patent Application Publication
(10) Pub. No.: US 2015/0294868 A1
(43) Pub. Date: Oct. 15, 2015

(54) Method of Manufacturing Semiconductor Devices Containing Chalcogen Atoms

(71) Applicant: Infineon Technologies AG, Neubiberg (DE)

(72) Inventors: Gerhard Schmidt, Wernberg (AT); Josef Riss, Einoede (AT); Thomas Neidhart, Klagenfurt (AT)

(21) Appl. No.: 14/253,519

(22) Filed: Apr. 15, 2014

(51) Int. Cl. H01L 21/225; H01L 29/167; H01L 29/36; H01L 21/322

(52) U.S. Cl. CPC H01L 21/2253; H01L 21/3225; H01L 29/167; H01L 29/36

(57) ABSTRACT

Chalcogen atoms are implanted into a single crystalline semiconductor substrate. At a density of interstitial oxygen of at least 5E16 cm⁻³ thermal donors containing oxygen are generated at crystal defects in the semiconductor substrate. Then the semiconductor substrate is heated up to a temperature above a deactivation temperature at which the thermal donors become inactive, wherein a portion of electrically active chalcogen atoms is increased.

### BACKGROUND

Atoms of chalcogen elements have a comparatively high diffusion constant such that at moderate process temperatures between 900° C. and 1000° C. the chalcogen atoms may penetrate by more than 100 μm into a silicon crystal. For example, selenium atoms are implanted and diffused to form field stop layers at a rear side of high voltage IGBTs and high voltage semiconductor diodes. It is desirable to expand the field of application for chalcogen implants.

### SUMMARY

According to an embodiment a method of manufacturing a semiconductor device includes implanting chalcogen atoms into a single crystalline semiconductor substrate and, at a density of interstitial oxygen of at least 5E16 cm⁻³, generating thermal donors containing oxygen at crystal defects in the semiconductor substrate. Then the semiconductor substrate is heated up to a temperature above a deactivation temperature at which the thermal donors become inactive, wherein a portion of electrically active chalcogen atoms is increased.

According to a further embodiment a semiconductor device includes a single-crystalline semiconductor body with a first surface and a second surface parallel to the first surface. The semiconductor body has a vertical extension of at least 10 μm perpendicular to the first surface as well as a chalcogen concentration of at least 1E12 cm⁻³ and at most 1E16 cm⁻³. An electric active portion of the chalcogen atoms is greater than 3%.

Those skilled in the art will recognize additional features and advantages upon reading the following detailed description and on viewing the accompanying drawings.

### BRIEF DESCRIPTION OF THE DRAWINGS

The accompanying drawings are included to provide a further understanding of the disclosure and are incorporated in and constitute a part of this specification. The drawings illustrate the embodiments of the present disclosure and together with the description serve to explain principles of the disclosure. Other embodiments and intended advantages will be readily appreciated as they become better understood by reference to the following detailed description.

FIG. 1A is a schematic cross-sectional view of a portion of a semiconductor substrate for illustrating a method of manufacturing a semiconductor device according to an embodiment, during implantation of chalcogen atoms.

FIG. 1B is a schematic cross-sectional view of the semiconductor substrate portion of FIG. 1A after implanting the chalcogen atoms.

FIG. 1C is a schematic cross-sectional view of the semiconductor substrate portion of FIG. 1B after forming an auxiliary layer.

FIG. 1D is a schematic cross-sectional view of the semiconductor substrate portion of FIG. 1C after a first thermal treatment for diffusing the implanted chalcogen atoms.

FIG. 1E is a schematic cross-sectional view of the semiconductor substrate portion of FIG. 1D after an optional raising of TDs (thermal donors).

FIG. 1F is a schematic cross-sectional view of the semiconductor substrate portion of FIG. 1D or FIG. 1E after removing the auxiliary layer.

FIG. 1G is a schematic cross-sectional view of the semiconductor substrate portion of FIG. 1F after a second thermal treatment at a temperature above a dissociation temperature of the TDs.

FIG. 1H is a schematic cross-sectional view of the semiconductor substrate portion of FIG. 1G after thinning the semiconductor substrate.

FIG. 2 is a schematic diagram showing vertical profiles of the chalcogen concentration before and after the second thermal treatment.

FIG. 3A is a schematic cross-sectional view of a portion of a semiconductor device according to an embodiment.

FIG. 3B is a schematic diagram showing vertical profiles of chalcogen distributions for illustrating effects of the embodiments.

FIG. 4 is a schematic flow chart of a method of manufacturing a semiconductor device according to a further embodiment.

### DETAILED DESCRIPTION

In the following detailed description, reference is made to the accompanying drawings, which form a part hereof and in which are shown by way of illustrations specific embodiments in which the invention may be practiced. It is to be understood that other embodiments may be utilized and structural or logical changes may be made without departing from the scope of the present invention. For example, features illustrated or described for one embodiment can be used on or in conjunction with other embodiments to yield yet a further embodiment. It is intended that the present invention includes such modifications and variations. The examples are described using specific language, which should not be construed as limiting the scope of the appending claims. The drawings are not scaled and are for illustrative purposes only. For clarity, the same elements have been designated by corresponding references in the different drawings if not stated otherwise.

The terms “having”, “containing”, “including”, “comprising” and the like are open, and the terms indicate the presence of stated structures, elements or features but do not preclude additional elements or features. The articles “a”, “an” and “the” are intended to include the plural as well as the singular, unless the context clearly indicates otherwise.

The term “electrically connected” describes a permanent low-ohmic connection between electrically connected elements, for example a direct contact between the concerned elements or a low-ohmic connection via a metal and/or highly doped semiconductor. The term “electrically coupled” includes that one or more intervening element(s) adapted for signal transmission may be provided between the electrically coupled elements, for example elements that are controllable to temporarily provide a low-ohmic connection in a first state and a high-ohmic electric decoupling in a second state.

The Figures illustrate relative doping concentrations by indicating “−” or “+” next to the doping type “n” or “p”. For example, “n⁻” means a doping concentration which is lower than the doping concentration of an “n”-doping region while an “n⁺”-doping region has a higher doping concentration than an “n”-doping region. Doping regions of the same relative doping concentration do not necessarily have the same absolute doping concentration. For example, two different “n”-doping regions may have the same or different absolute doping concentrations.

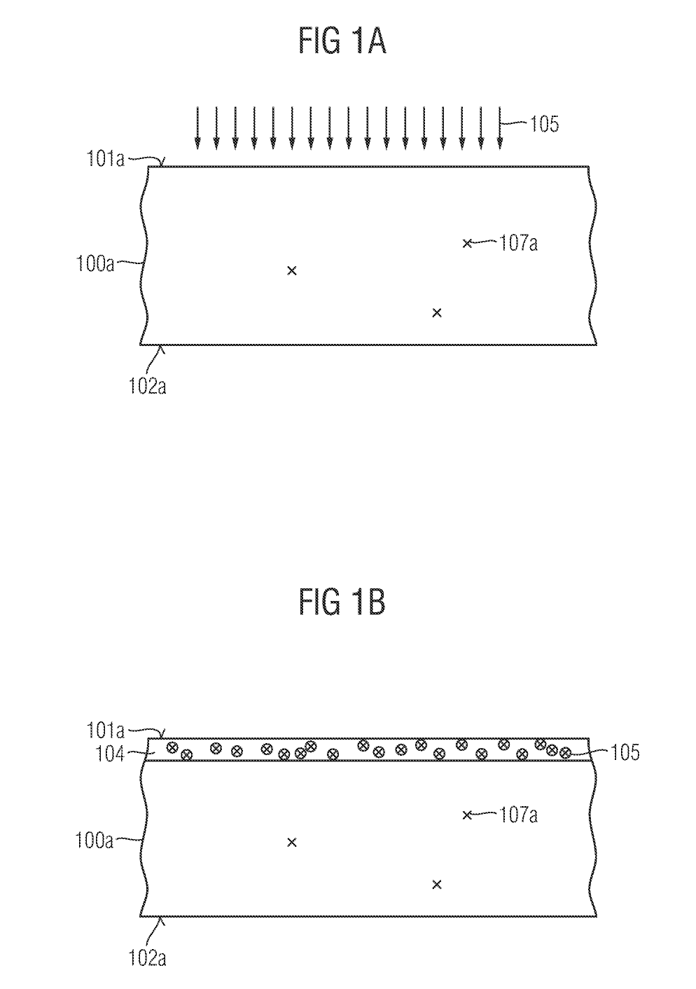

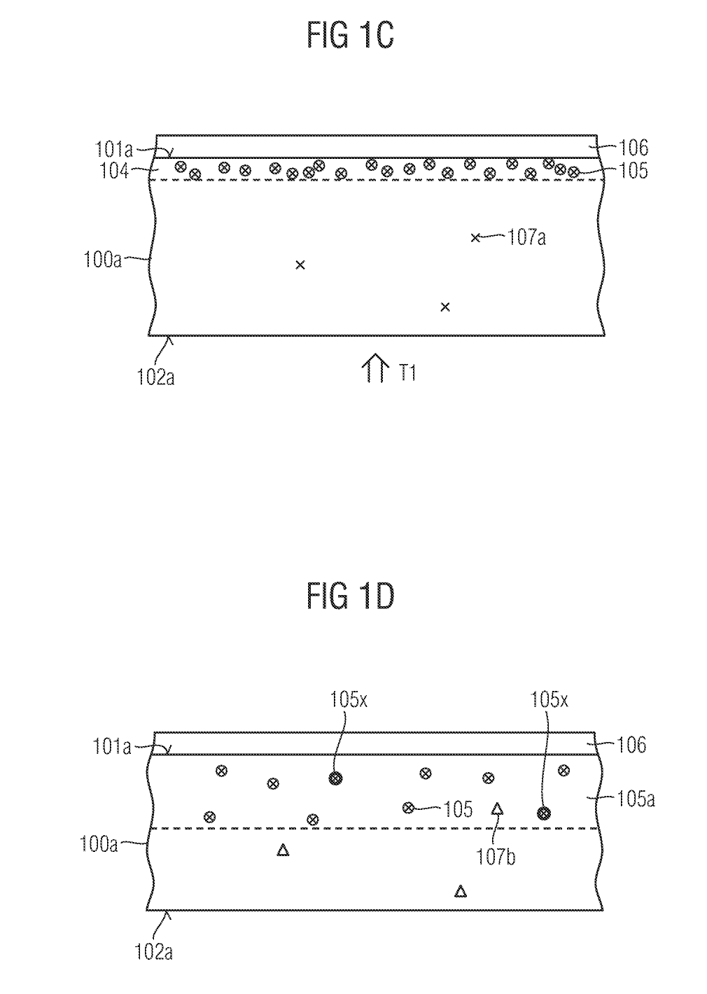

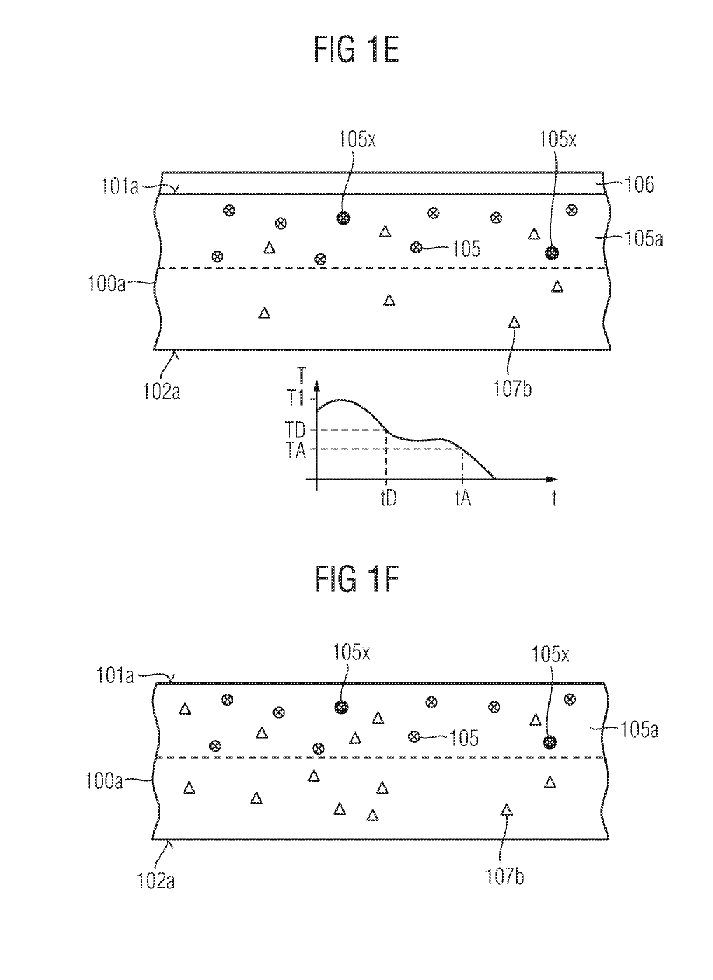

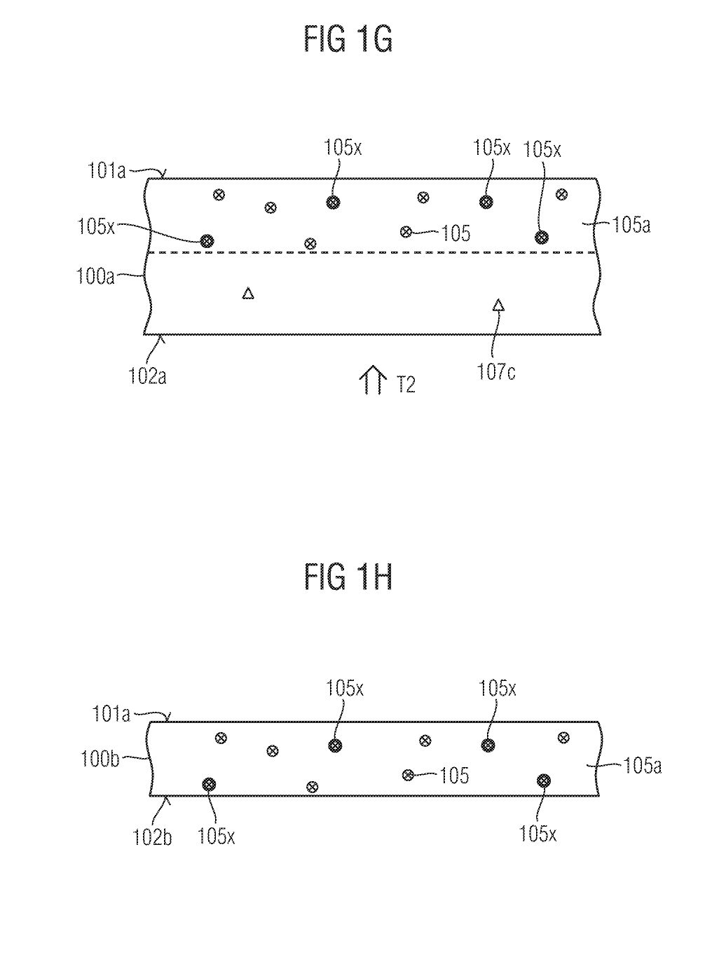

FIGS. 1A to 1E illustrate the forming of a layer or substrate containing approximately homogenously distributed chalcogen atoms, wherein thermal donors enhance the electrical activation of the chalcogen atoms.

A semiconductor substrate 100a may be a semiconductor wafer, for example a silicon wafer, an SOI (silicon-on-insulator) wafer, e.g. an SOG (silicon-on-glass) wafer or a substrate of another single-crystalline semiconductor material such as silicon carbide SiC, gallium arsenide GaS, gallium nitride GaN or another A_{III}B_{V} semiconductor, germanium Ge or a silicon germanium crystal SiGe. According to an embodiment the semiconductor substrate 100a is a silicon wafer obtained by a Czochralski process, for example an m:Cz (magnetic Czochralski) silicon wafer.

The semiconductor substrate 100a may have a first surface 101a and a second surface 102a parallel to the first surface 101a as shown in FIG. 1A. In the following a perpendicular to the first surface 101a defines a vertical direction and directions parallel to the first surface 101a are horizontal directions. The semiconductor substrate 100a may contain non-doping impurity atoms such as interstitial oxygen atoms. According to an embodiment the semiconductor substrate 100a is an m:Cz silicon wafer with a content of interstitial oxygen atoms 107a of at least 5E16 cm⁻³, for example at least 1E17 cm⁻³, wherein the m:Cz silicon wafer is obtained from a silicon ingot grown in a magnetic Czochralski process. According to another embodiment, the content of interstitial oxygen is at least 2E17 cm⁻³.

Chalcogen atoms 105, for example selenium (Se), sulfur (S) or tellurium (Te) atoms are implanted through the first surface 101a. According to an embodiment, the chalcogen atoms 105 are ⁸⁰Se atoms implanted at a dose in a range from 1E13 cm⁻², to 1E15 cm⁻² at an energy in a range from 10 keV to 500 keV.

FIG. 1B shows a chalcogen implant layer 104 containing the implanted chalcogen atoms 105. The chalcogen implant layer 104 directly adjoins the first surface 101a. The thickness of the chalcogen implant layer 104 is a function of the implantation energy.

Before or after implanting the chalcogen atoms 105 self-interstitials are generated in the semiconductor substrate 100a. In case the semiconductor substrate 100a is a silicon crystal, the self-interstitials are silicon atoms at interstitial lattice sites.

According to an embodiment illustrated in FIG. 1C, the self-interstitials are generated by forming an auxiliary layer 106 on the first surface 101a. The auxiliary layer 106 may be a thermal oxidation layer inducing stress into the crystal lattice of the semiconductor substrate 100a or a layer containing auxiliary atoms which are able to promote diffusion of the respective chalcogen atom in the semiconductor substrate 100a. The auxiliary layer 106 may be a phosphoric glass formed in an atmosphere including a precursor containing phosphorus, for example POCl₃ or PH₃. According to an embodiment, the auxiliary layer 106 is phosphoric glass formed by an anneal lasting at least 20 minutes at a temperature of at least 900° C. in an atmosphere containing PH₃. The phosphorus atoms displace to some degree atoms of the crystal lattice and thereby generate interstitial atoms. Outdiffusion of phosphorus atoms from the auxiliary layer 106 or during the formation of the auxiliary layer 106 locally oversaturates the semiconductor substrate 100a with crystal interstitials, e.g. Si interstitials in a silicon crystal. The diffusion from an infinite source that does not exhaust within the time of interest, for example the auxiliary layer 106, leads to a permanent subsequent supplying of silicon interstitials that in turn promote the diffusion of the implanted chalcogen atoms.

FIG. 1C shows the auxiliary layer 106 on the first surface 101a as well as interstitial oxygen atoms 107a distributed in the semiconductor substrate 100a.

A first high temperature anneal is performed to diffuse the chalcogen atoms 105 from the chalcogen implant layer 104 into further portions of the semiconductor substrate 100a. The first high temperature anneal is performed at a first temperature T1 greater than a minimum diffusion temperature TDiff for the chalcogen atoms 105, which is about 900° C. for selenium in silicon. The interstitial silicon atoms displaced from the lattice points, e.g. by the auxiliary atoms, promote the diffusion of the chalcogen atoms by kicking them out and ousting them from the lattice points. The chalcogen implant layer 104 of FIGS. 1C expands to a diffused chalcogen layer 105a whose width depends on the applied thermal budget.

The high temperature anneal causes the chalcogen atoms 105 to diffuse deeper into the semiconductor substrate 100a, wherein the self-interstitials accelerate or support the diffusion and the presence of the auxiliary atoms keeps the density of self-interstitials high. According to an embodiment, the first high temperature anneal lasts at least 20 minutes at a temperature greater than 900° C. and lower than 1100° C.

During cooling down from the first temperature T1 the semiconductor substrate 100a passes a temperature range between an activation temperature TA at which TDs (thermal donors) 107b may be formed, and below a deactivation temperature TD, at which the thermal donors 107 may annihilate or dissociate into inactive species. Such thermal donors are generated when in the temperature range between TA and TD, the interstitial oxygen interacts with certain types of crystal defects in the semiconductor crystal lattice, e.g. the silicon lattice. The crystal defects may be vacancies or self-interstitials, by way of example. The thermal donors 107b may include TDDs (deep thermal double donors), which are interpreted as oxygen-containing complexes with three or more oxygen atoms, as well as STDHs (shallow thermal donators) which additionally contain hydrogen atoms.

FIG. 1D shows the diffused chalcogen layer 105a having a greater vertical extension than the chalcogen implanted layer 104 of FIG. 1C. The vertical extension of the diffused chalcogen layer 105a may be at least 10 μm. According to an embodiment, the vertical extension of the diffused chalcogen layer 105a is between 20 and 300 μm. At most 1% of the chalcogen atoms are electrically active chalcogen atoms 105x. The semiconductor substrate 100a further contains thermal donors 107b.

Optionally, the concentration of thermal donors 107b may be further enhanced by prolonging, in the cooling phase from the first temperature T1, the time the semiconductor substrate 100a is above the activation temperature TA and below the deactivation temperature TD.

According to an embodiment, the cooling may pause at temperatures between at least 300° C. and at most 550° C., e.g. at about 460° C. for at least five, e.g. 10 or 30 minutes. According to an embodiment, the cooling phase may last for at least 1E5 s. According to a further embodiment, the semiconductor substrate 100a may be subjected to a discrete thermal treatment at a temperature between TA and TD anytime between the first high temperature anneal for diffusing the implanted chalcogen atoms and a second high temperature anneal above TD.

FIG. 1E shows an increased density of thermal donors 107b after the first high temperature anneal at the first temperature T1 with an extended cooling phase between 300° C. and 550° C. The first high temperature anneal may be performed in the presence of the auxiliary layer 106, which may be removed after the first thermal anneal.

FIG. 1F shows the semiconductor substrate 100a after removal of the auxiliary layer 106 of FIG. 1E. In addition to the auxiliary layer 106 a portion of the semiconductor substrate 100a close to the first surface 101a and including a high density of auxiliary atoms may be removed. According to an embodiment a layer containing a high concentration of auxiliary atoms and with a thickness of several micrometers, e.g. in a range from 5 μm to 15 μm, may be removed.

Further in the course of processing, the semiconductor substrate 100a is subjected to a second high temperature anneal at a temperature T2 which is higher than the deactivation temperature TD such that the thermal donors are deactivated, e.g. the thermal donors are annihilated or dissociated. Thereby the implanted chalcogen atoms 105 interact with thermal donors 107 in the way that the presence of the thermal donors 107 or their dissipation increases the ratio of electrically active chalcogen atoms 105x.

The second high temperature anneal may be any high temperature anneal applied later in a process sequence for manufacturing semiconductor devices on the basis of the semiconductor substrate 100a, for example a thermal oxidation process or an anneal exclusively dedicated to the disintegration of thermal donors to increase the active chalcogen ratio.

FIG. 1G shows the semiconductor substrate 100a after the second high temperature anneal. The presence of the thermal donors or the dissociation of the thermal donors 107b of FIG. 1F activates some of the previously inactive selenium atoms 105 such that the portion of electrically active selenium atoms 105x is increased. The thermal donors 107b of FIG. 1F have disappeared. Instead, new thermal donors 107c may be formed when the semiconductor substrate 100a cools down from the second temperature T2.

The semiconductor substrate 100a may be thinned from the second surface 102a such that the diffused chalcogen layer 105a extends over a main portion of a remaining substrate 100b or the complete remaining substrate 100b. The thinning may take place directly after the second high temperature anneal and before further front side processing. According to another embodiment, the semiconductor substrate 100a may be thinned after the front side processing, for example, after forming transistor cells or after forming contacts to doped areas along the first surface 101a.

FIG. 1H shows the remaining substrate 100b after removing the auxiliary layer 106 and a portion of the semiconductor substrate 100a into which the chalcogen atoms 105 have not diffused to a significant degree.

During the second high temperature anneal and during further high temperature anneals a vertical concentration profile of the chalcogen atoms becomes increasingly smoother such that in a finalized semiconductor device a semiconductor body obtained from the remaining substrate 100b may have an approximately homogeneous distribution of the implanted chalcogen atoms. In addition, during any further high temperature anneal above the deactivation temperature TD, previously formed thermal donors 107c are deactivated and dissociated or annihilated in a way that interacts with the chalcogen atoms and that may further increase the portion of electrical active chalcogen atoms.

Where according to conventional approaches only about 1% of the implanted selenium dose is electrically active as dopant in a finalized semiconductor device, the interaction of the implanted chalcogen atoms 105 with the thermal donors 107b and, if applicable, thermal donors 107c increases the portion of electrically active chalcogen atoms to beyond at least 3%. Less chalcogen atoms have to be implanted for achieving the same dopant effect. Where the implant dose for the chalcogen atoms is subject to limitations, higher active chalcogen concentrations can be achieved. The field of application of chalcogen based impurity regions is enhanced.

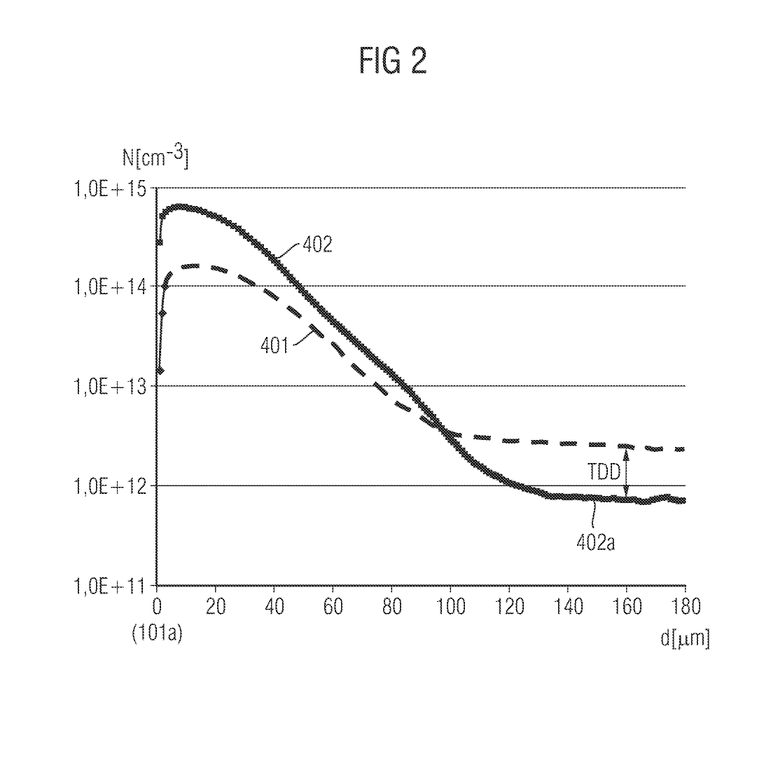

FIG. 2 is a diagram illustrating vertical effective dopant concentration profiles at different stages of a manufacturing process at an implanted selenium dose of 1E14 cm⁻³ and an implant energy of 170 keV.

Dopant profile 401 shows an effective dopant concentration indicating the electric active selenium distribution after a first high temperature anneal at 1100° C. lasting four hours for diffusing selenium atoms into an m:Cz silicon wafer having an intrinsic concentration of interstitial oxygen between 5E16 cm⁻³ and 1E18 cm⁻³, for example about 2E17 cm⁻³, wherein the diffusion is promoted by phosphorus atoms in a PH₃ ambient.

After the first high temperature anneal the concentration of the thermal donors is in the range of 2.3E12 cm⁻² and reduces the resistance of the semiconductor substrate from 6000 Ωcm to about 1879 Ωcm. After removal of a phosphorus source a second high-temperature anneal is performed at a temperature above 900° C. Close to a first surface at d=0 a high number of phosphorus atoms produces a high number of self-interstitials and thermal donors. With increasing distance d to the first surface, less phosphorus atoms generate less self-interstitials and less thermal donors. The comparatively high number of silicon interstitials and thermal donors for short distances d result in a higher portion of electrical effective selenium atoms close to d=0. The number of activated selenium atoms decreases with increasing distance to the first surface 101a. In the resulting second doping profile 402, the maximum concentration is further increased close to the first surface 101a.

The electric active selenium dose may increase from 6.8E11 cm⁻² to 2.2E12 cm⁻². A significant decrease in a tail portion 402a of the second dopant profile 402 may be at least in parts a result of the extinction of the thermal donors whose deactivation decreases the effective dopant concentration.

The second high temperature anneal may be included in a manufacturing process for providing semiconductor devices from the remaining substrate 100b of FIG. 1F. For example, the second high temperature anneal may be applied in the course of a wet oxide process at 1000° C. and may last for about 8 hours for forming a thermal oxide having a thickness of 1 μm or more on, e.g., the first surface 101a. Further process steps that may be effective as the second high temperature anneal may be the gate oxidation, a diffusion of a floating p-doped zone in an edge area, as well as a diffusion process for implanted body zones. Any further high temperature anneal that supplies temperatures between 1100° C. and 1200° C. further smoothens the vertical concentration profile of the implanted chalcogen atoms and may contribute to an approximately uniform dopant level of electrically active selenium atoms in the remaining substrate 100b of FIG. 1F.

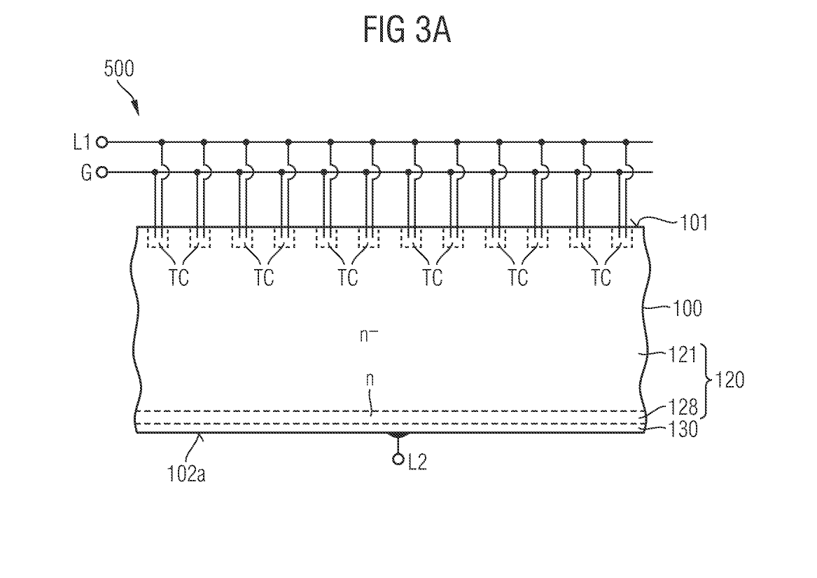

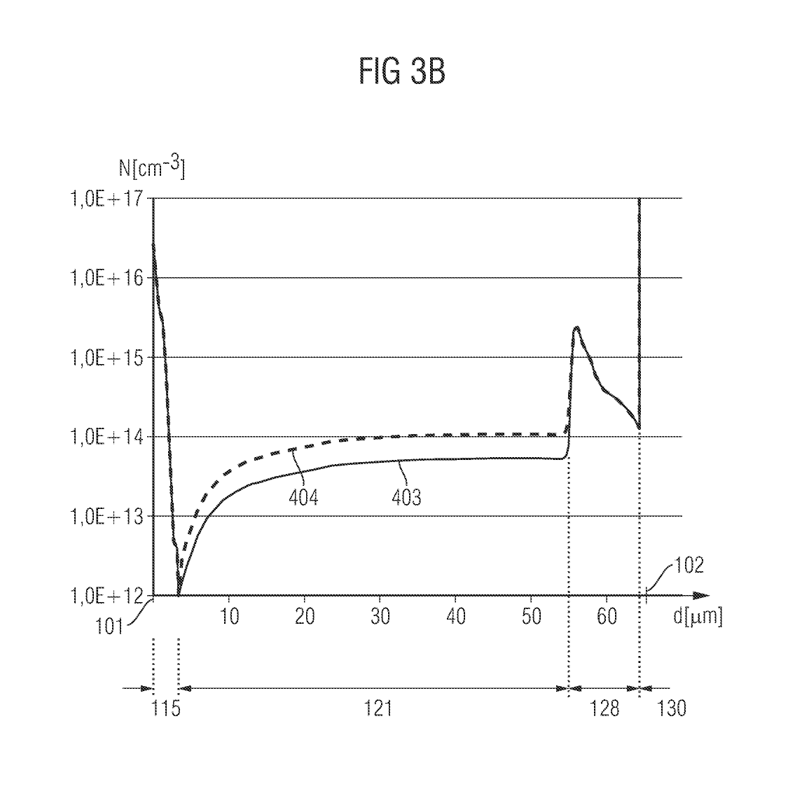

FIG. 3A refers to a semiconductor device 500 such as a semiconductor diode, an IGFET (insulated gate field effect transistor), an IGBT (insulated gate bipolar transistor), e.g., an RC-IGBT (reverse conducting IGBT), a BJT (bipolar junction transistor), a thyristor, a GTO (gate turn-off thyristor) or a radiation detector diode.

A single-crystalline semiconductor material, for example silicon (Si), silicon carbide (SiC), germanium (Ge), a silicon germanium crystal (SiGe), gallium nitride (GaN), gallium arsenide (GaAs) or another A_{III}B_{V} semiconductor forms a semiconductor body 100 with a first surface 101, which may be approximately planar or which may be defined by a plane spanned by coplanar surface sections, as well as a mainly planar second surface 102 parallel to the first surface 101.

A minimum distance between the first and second surfaces 101, 102 depends on a voltage blocking capability the semiconductor device 500 is specified for. For example, the distance between the front and second surfaces 101, 102 may be in a range from 90 μm to 200 μm for a semiconductor device specified for a blocking voltage of about 1200 V. Other embodiments related to semiconductor devices with higher blocking capabilities may provide semiconductor bodies 100 with a thickness of several 100 μm. Semiconductor devices with lower blocking capabilities may have a thickness from 35 μm to 90 μm.

In a plane parallel to the first surface 101 the semiconductor body 100 may have a rectangular shape with an edge length in the range of several millimeters.

The semiconductor body 100 includes a base region 120 with an n-type drift zone 121. At the front side of the semiconductor body 100 along the first surface 101 transistor cells TC of an IGFET, an IGBT or an RC-IGBT may form conductive channels connected with the drift zone 121 in a first state of the semiconductor device 500. The transistor cells TC allow electrons to pass into the drift zone 121 in the first state of the semiconductor device 500, which may correspond to a forward conducting mode.

A pedestal layer 130 is sandwiched between the base region 120 and a rear side electrode directly adjoining the second surface 102. The pedestal layer 130 directly adjoins the rear side electrode and may directly adjoin the drift zone 121.

The pedestal layer 130 may be an n-type layer for semiconductor diodes and IGFETs, a p-type layer in case of non-reverse conducting IGBTs or a layer containing both n-type and p-type zones in case the semiconductor device 500 is an RC-IGBT. A dopant concentration in the pedestal layer 130 is sufficiently high for providing an ohmic contact with a metal electrode directly adjoining the second surface 102.

According to other embodiments, further doped layers or zones such as a field stop layer 128 may be formed between the drift zone 121 and the pedestal layer 130.

The transistor cells TC may be IGFET (insulated gate field effect transistor) cells with an n-type source zone and a p-type body zone separating the source zone from the drift zone 121. The source zones may be electrically connected or coupled to a first load terminal L1 of the semiconductor device 500. The pedestal layer 130 may be electrically connected with a second load terminal L2.

Gate electrodes of the transistor cells TC may be electrically connected or coupled to a gate terminal G and are capacitively coupled to the body zones through gate dielectrics. Subject to a voltage applied to the gate terminal G, an inversion channel formed in the body zone provides an electron current through the transistor cell TC such that electrons enter the drift zone 121 through the transistor cell TC in the first state of the semiconductor device 500, which may correspond to a forward conducting mode including a transistor mode and an IGBT mode of an IGBT or to a desaturation mode of other semiconductor devices.

In addition to the source zones 110, the body zones 115 as well as additional p-type anode zones may be electrically connected or coupled to the first load terminal L1. The body zones 115 as well as the anode zones inject holes into the drift zone 121 in a second state of the semiconductor device 500, wherein the second state may correspond to a reverse conducting mode of an RC-IGBT, by way of example. The transistor cells TC may be planar-gate cells with planar gate electrodes arranged outside a contour of the semiconductor body 100 or trench-gate cells with trench electrodes extending into the semiconductor body 100. For example, the source and body zones of the transistor cells TC may be formed in semiconductor mesas separated by trench-gate structures.

In addition to the drift zone 121 and the field stop layer 128, the base region 120 may include various further doped layers and zones, for example barrier layers increasing the plasma density at a side of the base region 120 oriented to the transistor cells TC, a super junction structure for increasing the voltage blocking capabilities at a comparatively high impurity concentration in the drift zone 121 as well as counter-doped islands of the second conductivity type.

The drift zone 121 may contain approximately homogeneously distributed chalcogen atoms, for example selenium atoms. A mean chalcogen concentration in the drift zone 121 may be between 1E12 cm⁻³ and 1E16 cm⁻³, e.g. in a range from 1E13 cm⁻³ to 1E14 cm⁻³. At least 3% of the chalcogen atoms, for example at least 5% or even 10%, are electrically active in the operation modes of the semiconductor device 500.

The drift zone 121 may be formed as discussed above with regard to FIGS. 1A to 1F. The field stop layer 128 may be formed by a proton implant through the second surface 102. The pedestal layer 130 may be formed by phosphorus, boron or arsenic atoms implanted through the second surface 102.

FIG. 3B is a diagram showing the result of the analysis of a semiconductor diode obtained from the process of FIGS. 1A to 1F on the basis of an m:Cz silicon wafer. A vertical cross-section of the semiconductor diode may correspond to an embodiment of the semiconductor device 500 of FIG. 3A without transistor cells.

A drift zone 121 in a center portion of the semiconductor diode is formed from implanted and diffused selenium atoms. A proton implant through the second surface 102 forms a field stop layer 128 adjoining the drift zone 121. A phosphorus implant through the second surface 102 may form a pedestal layer 130 sandwiched between the field stop layer 128 and the second surface 102. A boron implant through the first surface 101 may form an anode layer 115 between the first surface 101 and the drift zone 121. The boron implant overcompensates the selenium atoms in the anode layer 115 and partially reduces the doping effect of the selenium atoms up to a distance of about 3 μm to 10 μm to the first surface 101.

A first doping profile 403 is obtained by SRP (spreading resistance analysis) of the semiconductor diode. During SRP the double donor selenium atoms are in a single ionized state, respectively. A second doping profile 404 is obtained by a C(U) (capacity-voltage) measurement determining the capacity with a blocking voltage applied to the semiconductor diode. The blocking voltage lowers the Fermi level to far below the thermodynamic equilibrium value and the double donor selenium atoms are fully (double) ionized. As a result, the second doping profile 404 corresponds to the double ionized state of the substitutional selenium centers.

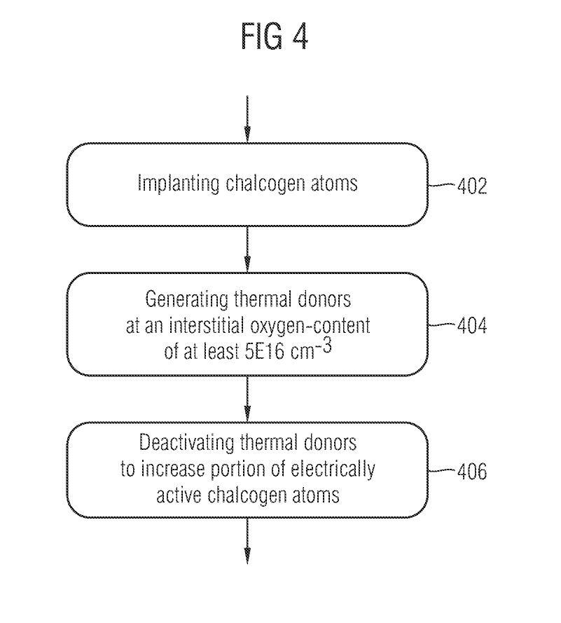

FIG. 4 refers to a method of manufacturing a semiconductor device. Chalcogen atoms are implanted into a single crystalline semiconductor substrate (402). Thermal donors containing oxygen are formed as a consequence of oxygen content in the semiconductor substrate, where a concentration of interstitial oxygen exceeds a value of 5E16 cm⁻³ (404). Then the semiconductor substrate is tempered at a temperature above a deactivation temperature, at which the thermal donors become inactive and increase a portion of electrically active chalcogen atoms (406).

With respect to an implanted selenium dose the thermal donors increase the portion of the electric active selenium atoms from about 1% or less to at least 3%, for example to at least 5% or even 10%. The doping level achievable in the drift zone for m:Cz silicon wafer can so be adjusted to the donor density typically achieved for FZ (floating zone) silicon wafers with phosphorus atoms introduced during the crystal growth.

Therefore the method as described above allows the replacement of expensive FZ wafers with less expensive m:Cz wafers for the manufacture of vertical semiconductor devices with a drift zone having a vertical extension of more than 10 μm.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method of manufacturing a semiconductor device, the method comprising:
implanting chalcogen atoms into a single crystalline semiconductor substrate;
generating thermal donors containing oxygen at crystal defects in the semiconductor substrate at a density of interstitial oxygen of at least 5E16 cm⁻³; and then
heating the semiconductor substrate up to a temperature above a deactivation temperature at which the thermal donors become inactive, wherein a portion of electrically active chalcogen atoms is increased.

2. The method of claim 1, wherein
the thermal donors are generated in a cooling phase of a first high temperature anneal above 900° C. for diffusing the chalcogen atoms.

3. The method of claim 2, further comprising:
introducing auxiliary impurities into the semiconductor substrate for increasing a density of interstitial semiconductor atoms before the first high temperature anneal.

4. The method of claim 3, wherein
the auxiliary impurities are phosphorus atoms.

5. The method of claim 3, further comprising:
removing an auxiliary layer predominantly containing the auxiliary impurities after the first high temperature anneal.

6. The method of claim 1, wherein
the semiconductor substrate is a Czochralski silicon wafer obtained from a Czochralski-grown silicon ingot.

7. The method of claim 2, wherein
a cooling phase of the first high temperature anneal pauses for at least 5 minutes in a temperature range above an activation temperature of the thermal donors and below a deactivation temperature of the thermal donors.

8. The method of claim 7, wherein
the cooling phase lasts for at least 1E5 s.

9. The method of claim 1, wherein
the chalcogen is selenium.

10. The method of claim 1, wherein
the semiconductor substrate is a silicon crystal.

11. A semiconductor device, comprising:
a single-crystalline semiconductor body with a first surface and a second surface parallel to the first surface, the semiconductor body having a vertical extension of at least 10 μm perpendicular to the first surface as well as a chalcogen concentration of at least 1E12 cm⁻³ and at most 1E16 cm⁻³, wherein an electric active chalcogen portion is greater than 3%.

12. The semiconductor device of claim 11, wherein
the electric active chalcogen concentration portion is greater than 1E12 cm⁻².

13. The semiconductor device of claim 11, wherein
the chalcogen is selenium.

14. The semiconductor device of claim 11, wherein
the semiconductor substrate is a silicon crystal.

15. The semiconductor device of claim 11, further comprising:
a drift zone having an effective net dopant concentration given by the chalcogen content in the drift zone.
